(19) United States
(12) Patent Application Publication
(10) Pub. No.: US 2005/0246115 A1
(43) Pub. Date: Nov. 3, 2005

(54) Waveform display apparatus

(75) Inventor: Toshihiko Sakurai, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: YOKOGAWA ELECTRIC CORPORATION, Tokyo (JP)

(21) Appl. No.: 11/103,574

(22) Filed: Apr. 12, 2005

(30) Foreign Application Priority Data
Apr. 14, 2004 (JP) 2004-118961

(51) Int. Cl. G01R 13/02

(52) U.S. Cl. 702/67

(57) ABSTRACT

A waveform display apparatus is realized in which it is easy to distinguish whether waveform data is being compressed and displayed under a cursor. The present invention adds an improvement to a waveform display apparatus, in which the waveform data of a waveform that is measured is displayed as a waveform in a display device and the cursor for waveform analysis is displayed. This apparatus further provides an icon display device that displays in a display device an icon that shows whether the waveform data is compressed and displayed in the time series direction.

### BACKGROUND OF THE INVENTION

1. Field of the Invention

The present invention relates to a waveform display apparatus that displays the measured waveform data as a waveform and displays a cursor for waveform analysis, and in particular, relates to a waveform display apparatus that allows easy determination of whether the waveform data that is being displayed under the cursor has been compressed.

Priority is claimed on Japanese Patent Applications No. 2004-118961, filed Apr. 14, 2004, the content of which is incorporated herein by reference.

2. Description of Related Art

Waveform display apparatuses such as oscilloscopes, paperless recorders and the like measure a waveform, convert the measurements to digital data, and store the measurements in memory as waveform data. In addition, the waveform display apparatuses display the waveform data on the display unit of the waveform measuring apparatus as waveforms. In addition, the waveform data in the memory is transferred to a personal computer, which is another waveform display apparatus, and displayed in the display unit of the personal computer as a waveform. Furthermore, the waveform display apparatus enlarges the waveform analysis of the waveform data at a position under a cursor and the waveform data in the box area that is surrounded by a plurality of cursors, and displays them as a waveform (refer, for example, to Citation 1: Japanese Unexamined Patent Application, First Publication, No. 2000-321306, paragraphs 0002 to 0004, and Citation 2: Japanese Unexamined Patent Application, First Publication, No. 2003-302424, paragraphs 0002 to 0006).

FIG. 6 is a drawing showing an example of the display of a conventional waveform display apparatus. In FIG. 6, the abscissa is the axis (specifically, the time axis) of the time series direction, and the ordinate is the amplitude. In addition, the waveform data is represented as a waveform in the measured time series order. Note that as one example, 16 waveform data points are displayed as a waveform without being compressed in the time series direction. Additionally, the waveform analysis is carried out by aligning the cursor C1 with the waveform data (the data for the seventh waveform in FIG. 6) that is being examined. As waveform analysis, for example, the amplitude value of the waveform data under the cursor C1 is displayed as a cursor value.

FIG. 7 is a drawing showing another example of the display of a conventional waveform display apparatus. In FIG. 7, each axis is identical to those in FIG. 6, and their explanation is omitted. Generally, in comparison to the resolution that can be displayed on a display unit, the waveform display apparatus stores at a higher time resolution the high-volume waveform data that is a sampling of the measured waveform. Therefore, when the amount of the waveform data is large, the waveform data is compressed and then displayed as a waveform in the time axis direction. For example, if the resolution that can be displayed on the abscissa is 1001 points, when the number of displayed waveform data points of the waveform data equal to or less than 1001 points, the waveform data is displayed as a waveform without compression. However, when the number of waveform data points is larger than this, the waveform data is compressed and displayed as a waveform. In FIG. 7, an example is shown in which all of the 1001000 points of the waveform data are displayed as a waveform.

When the display is compressed in this manner, for the waveform analysis of points under the cursor C1, a plurality of representative values of the waveform data (1001000 points/1001 points=1000 points) is displayed as a cursor value V1. Note that as a representative value, any one of the average value, maximum value, or minimum value of the 1000 points under the cursor C1 can be selected. In addition, in the upper right part of the screen, the number of waveform data points that are displayed is displayed as the number of displayed data points V2.

However, when the number of displayed data points V2 approaches the value of the resolution of the abscissa, it becomes difficult to determine whether the waveform data is being compressed and displayed. Thus, there is the problem that it become difficult to determine whether one point of waveform data is being displayed or a plurality of waveform data points is being displayed after compression under the cursor C1.

In addition, in the case of a compressed display, there is the problem that it is difficult to determine how many waveform data points are compressed and displayed under the cursor C1.

### SUMMARY OF THE INVENTION

It is an object of the present invention to provide a waveform display apparatus that allows easy determination of whether the waveform data is displayed under the cursor has been compressed.

In a first aspect of the invention, a waveform display apparatus, which displays a waveform of measured waveform data and displays a cursor for waveform analysis, provides an icon display device that displays an icon showing whether the waveform data is compressed and displayed in the time series direction in a display unit.

In a second aspect of the invention, a waveform display apparatus provides a numerical value display device that displays all waveform data present under the cursor as numerical values when the waveform data that is compressed and displayed.

In a third aspect of the invention, a waveform display apparatus, which displays as a waveform the measured waveform data and displays a box which specifies an area, provides an icon display device that displays an icon showing whether the waveform data is compressed and displayed in the time series direction in the display unit and a numerical value display device that displays all waveform data present in a box as numerical values when the waveform data is compressed and displayed.

In a fourth aspect of the invention, a numerical value display device displays as numerical values at least one of either the date that the data was measured, or the time that the data was measured, or the amplitude value.

In a fifth aspect of the invention, the numerical value display device carries out the waveform analysis using the waveform data whose numerical values are displayed, and displaying the results of the analysis.

According to the present invention, the following effects are attained:

According to the first, second, fourth, and fifth aspects of the present invention, when waveform data is compressed and displayed in the time series direction, the icon display device displays in the display unit an icon that shows that the display has been compressed, and thus it is possible to recognize easily whether the display has been compressed.

According to the second aspect, when the waveform data is compressed and displayed, the icon display unit displays in the display unit an icon that shows the display has been compressed, and thus it is possible to recognize easily whether the display has been compressed.

According to the third through fifth aspects, when the waveform data is compressed and displayed in the time series direction, the icon display device displays in the display unit an icon that shows that the display has been compressed. In addition, while the waveform data is compressed and displayed, the numerical value display device displays as numerical values all of the waveform data present in a box. Thereby, it is possible to recognize easily that the data is compressed and displayed and it is possible to recognize easily the details of the waveform data in the box. Thereby, it is possible to determine easily how much waveform data is being compressed and displayed in the box.

According to the fifth aspect of the invention, the numerical value display device displays the results of analysis after carrying out a waveform analysis by using only the waveform data that the numerical value display device is displaying as a numerical value.

### BRIEF EXPLANATION OF THE FIGURES

FIG. 1 is a structural diagram showing the first embodiment of the present invention.

FIG. 2 is a drawing showing an example of the display of the display device.

FIG. 3 is a drawing showing an example of the display of the numerical value display window.

FIG. 4 is a drawing showing another example of the display of the display part.

FIG. 5 is a drawing showing an example of the compressed display and the numerical value display.

FIG. 6 is a drawing showing an example of the display of the display unit in a conventional waveform display apparatus.

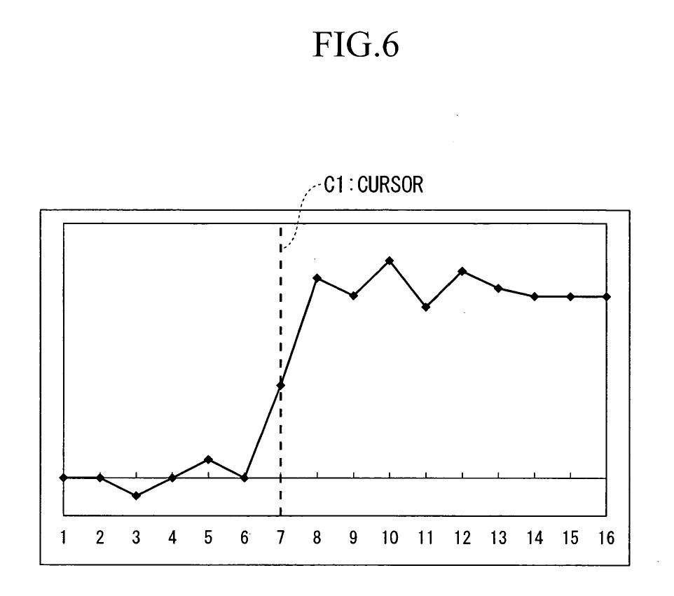

FIG. 7 is a drawing showing another example of the display (compressed display) of the display part in a conventional waveform display apparatus.

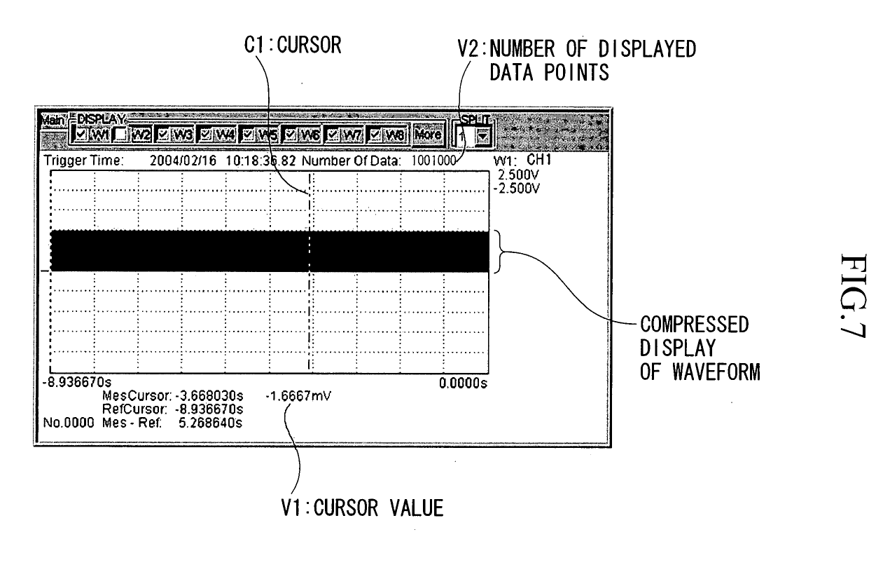

### DETAILED DESCRIPTION OF THE INVENTION

Below, the embodiments of the present invention will be explained with reference to the drawings.

### First Embodiment

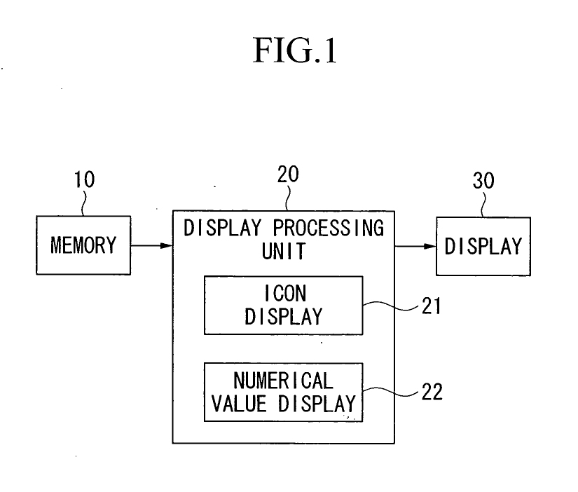

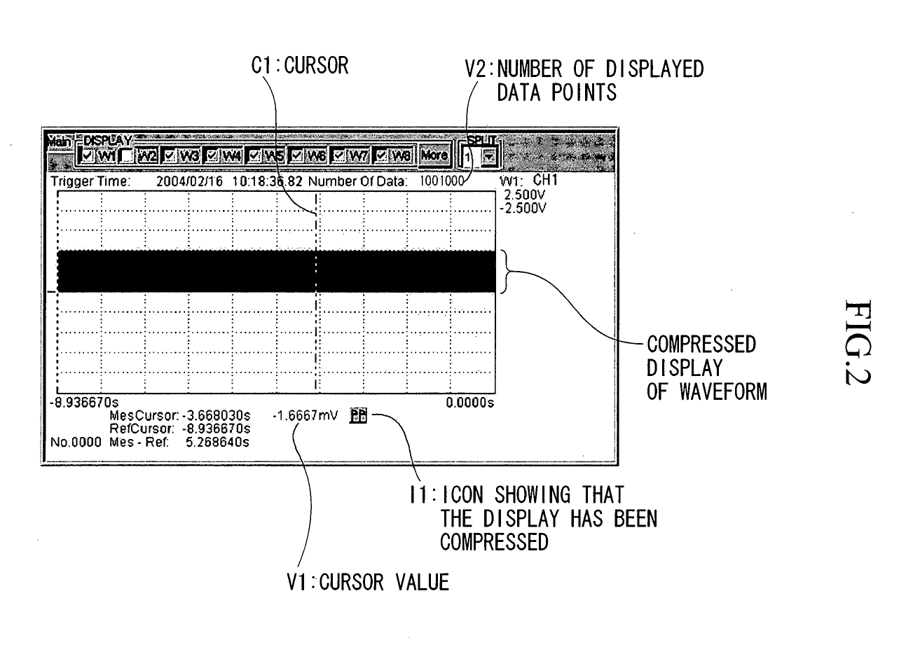

FIG. 1 is a structural drawing showing the first embodiment of the present invention. In addition, FIG. 2 is a drawing showing an example of the display of the apparatus shown in FIG. 1. In FIG. 1, a memory 10 is a storage unit that stores the waveform data of the measured waveform. A display processor 20 has an icon display device 21 and a numerical value display device 22. The waveform data of the memory 10 is read out, the waveform data is displayed as a waveform in a display unit 30, and at the same time, the cursor C1 for waveform analysis is displayed.

The icon display device 21 displays the icon that shows whether or not the waveform data is being compressed and displayed in the time series direction in the window that displays the waveform data as a waveform. The numerical value display device 22 displays a new window in the display unit 30 when the waveform data is compressed and displayed, and displays all waveform data present under the cursor C1 as a numerical value.

The operation of such an apparatus will now be explained.

The display processing unit 20 reads out the waveform data from the memory 10, and as shown in FIG. 2, a window having the appropriate size is created in the display unit 30, and the waveform data is displayed as a waveform. Note that the amount of the waveform data read out can be all data or set by the user from an input device (for example, a keyboard, mouse or the like; not illustrated). Then the display processing unit carries out the waveform analysis of the waveform data at the position on the time axis indicated by the cursor C1. Of course, in the case that the display has not been compressed, the amplitude value of the position indicated by the cursor C1 is displayed as the cursor value V1. As shown in FIG. 2, when the display has been compressed, a representative amplitude value under the cursor C1 is displayed as the cursor value V1. In addition, the display processing unit 20 displays the number of the display data points V2.

Then, when the data is compressed and displayed, the icon display device 21 displays an icon I1, that shows the display has been compressed, in proximity to the cursor value V1. Furthermore, when the icon I1 is clicked by an input device (not illustrated), the numerical value display device 22 displays anew a numerical value display window in the display part 30, and in this numerical value display window, all of the waveform data present under the cursor C1 is displayed as numerical values.

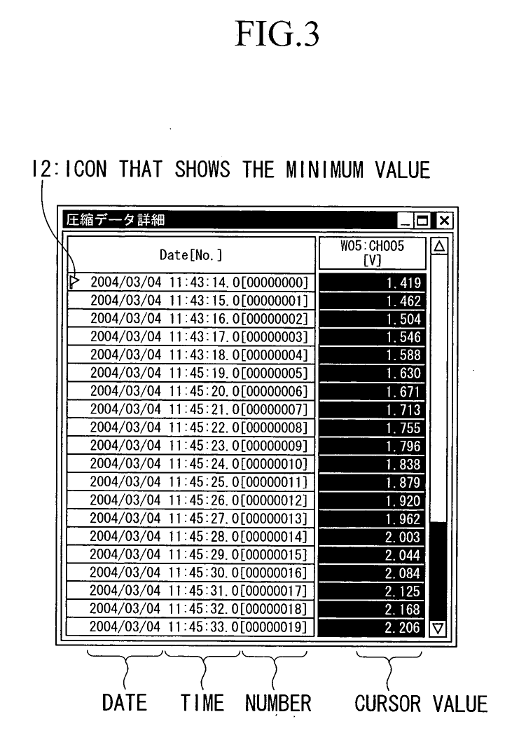

FIG. 3 is an example of the display of the numerical value display window. In FIG. 3, in the uppermost line, the page number (or Date[No. ], channel number and the like) is displayed. From the next line, the detailed numerical values of the waveform data are displayed, arranged one line each from the top in the time series order. In addition, for each of the waveform data, the date that the waveform data was measured, the time that the waveform data was measured, the serial number, and the amplitude value (cursor value) are displayed. Here, the date and time are referred to together as the data time ID.

Note that in the case that the waveform data under the cursor C1 in the numerical value display window cannot be displayed all at one time, a scroll bar is provided, and it is possible to select and display the desired waveform data by scrolling.

In addition, the numerical value display device 22 carries out waveform analysis, for example, analysis of the maximum value and minimum value, using the waveform data that is displayed as numerical values in the numerical value display window, and displays the icon I2 (in FIG. 3, the minimum value is displayed) for the index in the line of the characteristic waveform data that becomes the object depending on the result of this analysis.

When the waveform data is compressed and displayed in the time series direction in this manner, the icon display device 21 displays the icon I1, which indicates that the display is compressed, in the display device 30, and thereby it is possible to recognize easily whether the data is compressed and displayed. Therefore, it is possible to determine easily whether the waveform data that is undergoing waveform analysis under the cursor C1 is being compressed and displayed.

In addition, when the icon I1 is clicked while the waveform data is being compressed and displayed, the numerical value display device 22 displays all of the waveform data present under the cursor 1, and thereby it is possible to easily recognize the details of the waveform data under the cursor C1 from the data time ID, the serial number, the cursor value and the like. Thereby, it is possible to determine easily the amount of the waveform data is being compressed and displayed under the cursor C1.

Furthermore, because the numerical value display device 22 performs waveform analysis using only the waveform data under the cursor C1 and displays the icon I2 for the index according to the result of the analysis, it is easy to recognize the characteristic waveform data.

### Second Embodiment

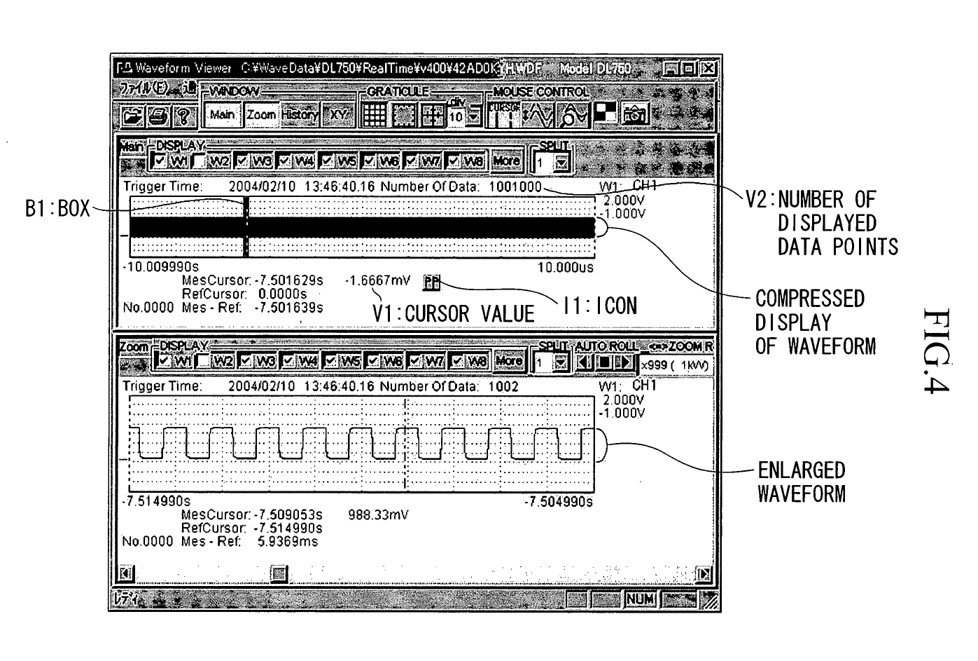

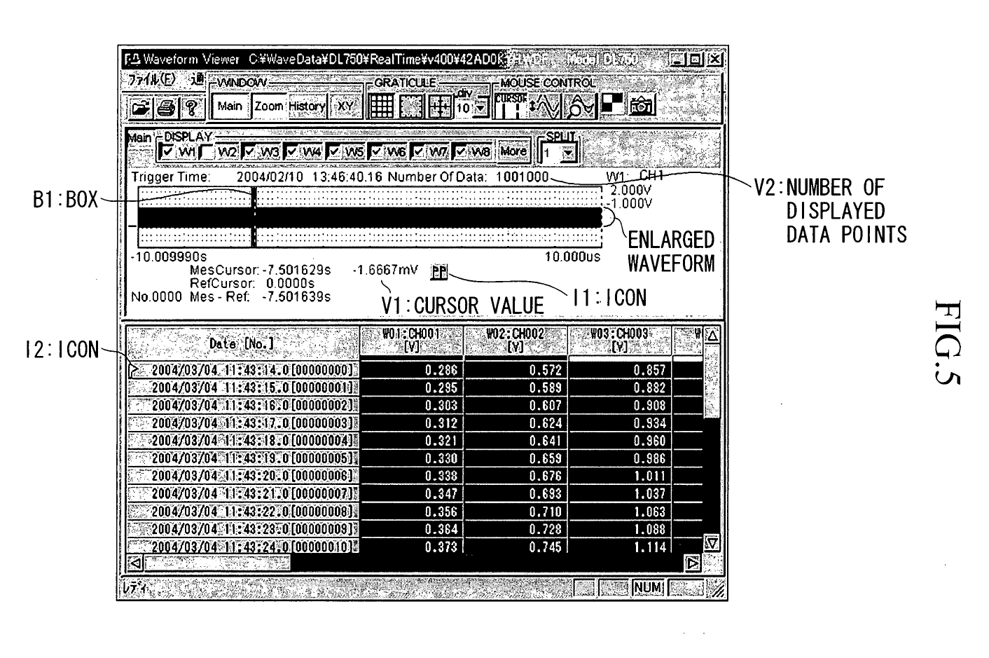

In the apparatus shown in FIG. 1, an example was explained in which the waveform data under the cursor C1 is displayed as numerical values. However, in the wave display apparatus, frequently waveform data in a rectangular box surrounded by a plurality of cursors is displayed after being enlarged and the waveform analysis carried out. The waveform data in such a box can be displayed as numerical values. The second embodiment will be explained with reference to FIG. 4 and FIG. 5. FIG. 4 is an example of a display in which a compressed waveform display and the waveform data in a box are enlarged and thereby the waveform displayed. FIG. 5 is an example of a display in which a compressed waveform display and waveform data in a box are displayed as numerical values.

The operation of the device will be explained. The display processing unit 20 read the waveform data from the memory 10, and displays the waveform. The display processing unit 20 displays an enlarged waveform, in which a part of the waveform data within an area indicated by a box B1 is enlarged, under the compressed waveform.

In addition, when the waveform data is compressed and displayed, the icon display device 21 displays an icon I1 that shows the display has been compressed in proximity to the cursor value V1. Furthermore, when the icon I1 is clicked using an input device (not illustrated), the numerical value display device 22 displays a numerical value display window in the display unit 30 instead of the window in which the enlarged waveform is displayed. In this numerical value display window, the display of the numerical values of all the waveform data present in the box B1 is carried out. Note that in FIG. 5, the amplitude value of a plurality of channels is displayed, and the icon I2 is displayed on the line of the waveform data that has the minimum value in the desired channel. 32

In this manner, when the waveform data is compressed and displayed in the time series direction, the icon display device 2I displays the icon I2, which shows that the display is compressed, in the display unit 30. In addition, when the icon I1 is clicked while the waveform data is being compressed and displayed, the numerical value display device 22 displays all of the waveform data present in the box B1 as numerical values. Thereby, it is possible to recognize easily whether the display is compressed, and it is possible to recognize easily the details of the waveform data in the box B1. Thereby, it is possible to determine easily the amount of waveform data that is being displayed in the box B1 after being compressed.

Note that the present invention is not limited by the above, and the following are also possible.

An example was shown in which the numerical value display device 22 displays the date that waveform data was measured, the time the waveform data was measured, and a serial number all in a numerical value display window, but it is also possible to display at least one of these.

In addition, an example was shown in which the numerical value display device 22 displays the icon I2 at the characteristic waveform data, but it is possible to change the color of the line in which the characteristic data is displayed, without displaying an icon. In short, it is possible to display the line in which the characteristic data is displayed such that it can be distinguished from other lines.

In addition, a structure was shown in which the numerical value display device 22 carries out analysis of the minimum value and the maximum value, but it is also possible to find the average value, distribution, or the like and display them in the next line in which the item is displayed. For example, it is also possible that to display “Average” in the second line of the Date [No. ] row and “SDev” in the third line, and display the average value and the distribution in each of the lines of the rows at which the cursor value is displayed. It is possible that the line in which the average value and the distribution are displayed cannot be scrolled.

A structure was shown in which a numerical value display device 22 is provided that displays the waveform data present under the cursor C1 as numerical values, but the numerical value display device 22 need not be provided.

Furthermore, an example was explained in which the thickness of the cursor C1 is equal to one point of the resolution on the abscissa, but the thickness of the cursor C1 can be equivalent to the thickness of a plurality of points.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. A waveform display apparatus that displays measured waveform data as a waveform and displays a cursor for waveform analysis comprises:
a display unit which displays the waveform; and
an icon display device that displays an icon that shows whether the waveform data is compressed and displayed in a time series direction in the display unit.

2. A waveform display apparatus according to claim 1 further comprising:
a numerical value display device that displays all waveform data present under the cursor as numerical values when the waveform data that is displayed has been compressed.

3. A waveform display device according to claim 2, wherein the numerical value display device displays as numerical values at least one of either the date that the data was measured, or the time that the data was measured, or the amplitude value.

4. A waveform display apparatus according to any of claim 2, wherein, the numerical value display device carries out waveform analysis using the waveform data whose numerical values are displayed, and displaying the results of the analysis.

5. A waveform display apparatus that displays measured waveform data as a waveform and displays a box which indicates an area comprises:
a display unit which displays the waveform;
an icon display device that displays an icon that shows whether the waveform data is compressed and displayed in the time series direction in the display unit; and
a numerical value display device that displays all waveform data present in the box as numerical values when the waveform data that is displayed has been compressed.

6. A waveform display device according to claim 5, wherein the numerical value display device displays as numerical values at least one of either the date that the data was measured, or the time that the data was measured, or the amplitude value.

7. A waveform display apparatus according to any of claim 5, wherein, the numerical value display device carries out waveform analysis using the waveform data whose numerical values are displayed, and displaying the results of the analysis.
